(19) United States
(12) Patent Application Publication
(10) Pub. No.: US 2021/0343791 A1
(43) Pub. Date: Nov. 4, 2021

(54) OLED DISPLAY PANEL, MANUFACTURING METHOD THEREOF, AND DISPLAY DEVICE THEREOF

(71) Applicant: SHENZHEN CHINA STAR OPTOELECTRONICS SEMICONDUCTOR DISPLAY TECHNONOGY CO., LTD., Shenzhen (CN)

(72) Inventor: Shiqi LIU, Shenzhen (CN)

(73) Assignee: SHENZHEN CHINA STAR OPTOELECTRONICS SEMICONDUCTOR DISPLAY TECHNONOGY CO., LTD., Shenzhen (CN)

(21) Appl. No.: 16/622,946

(22) PCT Filed: Nov. 19, 2019
(86) PCT No.: PCT/CN2019/119504

§ 371 Date: Dec. 16, 2019

(30) Foreign Application Priority Data
Oct. 23, 2019 (CN) 201911012832.4

(51) Int. Cl. H01L 27/32; H01L 51/56

(52) U.S. Cl. CPC H01L 27/322; H01L 27/3246; H01L 2227/323; H01L 51/56; H01L 27/3258

(57) ABSTRACT

An organic light emitting diode (OLED) display panel, a manufacturing method thereof, and a display device thereof are provided. The OLED display panel includes a substrate, and a thin film transistor (TFT) device functional layer is disposed on the substrate. A color resist layer is disposed on the TFT device functional layer, a planarization layer is disposed on the color resist layer, and an anode layer and an OLED light emitting layer are disposed on the planarization layer. Furthermore, a projection area of the planarization layer on the substrate is equal to a projection of the color resist layer on the substrate.

### CROSS REFERENCE TO RELATED APPLICATIONS

This is a U.S. National Phase Application under 35 U.S.C. § 371 of International Patent Application No. PCT/CN2019/119504, filed Nov. 19, 2019, and claims the priority of Chinese Patent Application No. CN201911012832.4 filed on Oct. 23, 2019; the title of the invention is “OLED DISPLAY PANEL, MANUFACTURING METHOD THEREOF, AND DISPLAY DEVICE THEREOF”, and all of which are incorporated by reference herein.

### FIELD OF INVENTION

The present disclosure relates to the field of flat-panel display technology, and particularly to an organic light emitting diode (OLED) display panel, a manufacturing method thereof, and a display device thereof among it.

### BACKGROUND OF INVENTION

As it is known, with continuous development of flat-panel display technology, new style flat-panel displays have begun to completely replace cathode ray tube (CRT) monitors, and have become the mainstream display devices in the market. Among them, liquid crystal displays (LCDs) were initially accepted by the market, and they were quickly accepted by the market due to their light and thin performance and were widely promoted to be used, so that their market share is very high.

However, with development of the display technology, LCDs still have certain defects on display performance, therefore, the industry is also continuously developing new style flat-panel display technology, and organic light emitting diode (OLED) displays are included among it.

The OLED displays have many advantages, such as self-illumination, low driving voltage, high luminous efficacy, short response times, high definition and high contrast, nearly 180 degrees viewing angle, wide temperature application range, can realize flexible display, full color display with large area, etc., which are applied extensively in display field, illumination field, wearable smart devices, and fields so on, and tend to replace LCDs.

With high requirements of display quality of panels from people, the problem of light leakage is gradually attached importance. Because light leakage will cause a color gamut value to be reduced, and the reduction of the color gamut will lower display quality of display images, color contrasts and color saturation are influenced.

Therefore, it is necessary to develop a new style OLED display panel to overcome the defects of the prior art.

### SUMMARY OF INVENTION

One aspect of the present disclosure is to provide an OLED display panel, and a new style structural design is used on a functional layer of the OLED display panel, so that the OLED display panel can prevent its pixel definition layer affecting a light path of outgoing light from its light emitting layer, and meanwhile, it can make the outgoing light from the light emitting layer be able to be performed a color filter process by its corresponding color resist layer.

The technical solutions which the present disclosure applies as follows:

An organic light emitting diode (OLED) display panel, including:

A substrate, and a thin film transistor (TFT) device functional layer is disposed on the substrate.

A color resist layer is disposed on a side of the TFT functional layer away from the substrate.

A planarization layer is disposed on the color resist layer.

An anode layer is disposed on a side of the planarization layer away from the color resist layer and is electrically connected to the TFT device functional layer by a first via hole.

An OLED light emitting layer is disposed on the anode layer.

Furthermore, a projection area of the planarization layer on the substrate is equal to a projection area of the color resist layer on the substrate.

That is, comparing to the prior art, coverage area of the planarization layer related to the present disclosure is relative less, and projection areas of the planarization layer and the color resist layer on the substrate are consistent, and the planarization layer makes the anode disposed thereon be flat, thereby preventing from a short circuit problem occurring between the cathode and the anode.

Furthermore, a disposing method of the planarization layer makes a coverage range of the planarization layer be consistent with a coverage range of the color resist layer in a light emitting area of the OLED light emitting layer. That is, the coverage area of the planarization layer in the light emitting area is equal to the coverage area of the color resist layer in the light emitting area, thereby ensuring the outgoing light from the OLED light emitting layer be able to be performed a color filter process by the color resist layer.

Further, in a different embodiment, a pixel definition layer is disposed on the TFT device functional layer, and the OLED light emitting layer is disposed on the pixel definition layer.

Further, in a different embodiment, a cathode layer is disposed on the OLED light emitting layer.

Further, in a different embodiment, a surface of the pixel definition layer is flush with a surface of the anode layer disposed on the planarization layer.

That is, heights of the pixel definition layer and the anode layer being planarization are kept being equal, and comparing it to the prior art that a surface of a pixel definition layer is higher than a surface of an anode layer and restricting the light emitting layer therein, in this way, it can effectively prevent from the pixel definition layer affecting the light path of the outgoing light of the light emitting layer (the OLED light emitting layer), and it can also improve the problem of the pixel definition layer having remained photoresist which is related to the prior art.

Furthermore, another aspect of the present disclosure is to provide a manufacturing method of the OLED display panel related to the present disclosure, including the following steps:

Step S1, providing the substrate, and forming the TFT device functional layer on the substrate.

Step S2, performing film formation and patterning of the color resist layer on the TFT device functional layer.

Step S3, performing film formation and patterning of the planarization layer on the color resist layer.

Step S4, performing film formation and patterning of the anode layer on the planarization layer.

Step S5, performing film formation and patterning of the pixel definition layer on the anode layer.

Step S6, manufacturing the OLED light emitting layer on the pixel definition layer.

Furthermore, in the step S3 and the step S4, after the patterning, projection areas of remained parts of the color resist layer and the planarization layer on the substrate are equal.

Further, in a different embodiment, in the step S3 and the step S4, after the color resist layer and the planarization layer are performed the film formation and then are patterned, coverage ranges of the remained color resist layer and the remained planarization layer in a light emitting area of the OLED light emitting layer are consistent.

Further, in a different embodiment, in the step S5, a height of a surface of the patterned pixel definition layer is consistent with a height of the anode layer on the planarization layer.

Further, in a different embodiment, in the step S6, the OLED light emitting layer is evaporated with its entire surface on the pixel definition layer.

Furthermore, another aspect of the present disclosure is to provide a display device, including the OLED display panel related to the present disclosure.

Relative to the prior art, the beneficial effect of the present disclosure is that the present disclosure relates to an OLED display panel, and a new style structural design is used on the functional layer of the OLED display panel, so that the OLED display panel can effectively prevent its pixel definition layer affecting a light path of outgoing light from its light emitting layer, and meanwhile, it can also make the outgoing light from the light emitting layer be able to be performed a color filter process by its corresponding color resist layer, and the related functional layer includes the planarization layer, the pixel definition layer, and the light emitting layer.

For the planarization layer, comparing a configuration way of a large coverage area of the planarization layer in the prior art, the present disclosure reduces the coverage area of the planarization layer and only remains the planarization layer on the OLED light emitting region, which makes the anode disposed thereon be flat, thereby preventing the short circuit problem between the anode and the cathode. A specific utilized method is that a coverage range of the planarization layer and a coverage range of the color resist layer disposed under the planarization layer are consistent, that is an area of the planarization layer is equal to an area of the color resist layer, thereby ensuring light emitted from the light emitting layer (the OLED light emitting layer of the present disclosure) is performed a color filter process by the color resist layer.

For the pixel definition layer, comparing it to a configuration way in the prior art that the pixel definition layer is higher than the anode layer and restricts the light emitting layer therein, the present disclosure controls a height of the pixel definition layer to be same as a height of the anode being planarization, that is, the heights of a top surface of the pixel definition layer and the surface of the anode being planarization are kept being equal, thereby effectively prevent from the pixel definition layer affecting the light path of the outgoing light, and it can also improve the problem of the remained photoresist of the pixel definition layer.

For the light emitting layer, comparing it to a configuration way in the prior art that the light emitting is disposed in the pixel definition layer, the present disclosure uses a method of evaporating an entire surface of the OLED light emitting layer on the pixel definition layer, and the light emitting region is defined to be a sandwich structural region constituted by an anode, an OLED device, and a cathode.

### DESCRIPTION OF DRAWINGS

In order to more clearly illustrate the technical solutions of the embodiments of the present disclosure, the accompanying figures of the present disclosure will be described in brief. Obviously, the accompanying figures described below are only part of the embodiments of the present disclosure, from which those skilled in the art can derive further figures without making any inventive efforts.

FIG. 1 is a structural schematic diagram of after finishing a step S1 of a manufacturing method of an OLED display panel provided by an embodiment of the present disclosure.

FIG. 2 is a structural schematic diagram of after finishing the manufacturing method mentioned in FIG. 1.

### DETAILED DESCRIPTION OF PREFERRED EMBODIMENTS

The technical solution of an organic light emitting diode (OLED) display panel, a manufacturing method thereof, and a display device thereof related to the present disclosure will be further described in detail as follow with reference to the accompanying drawings and embodiments.

Because the present disclosure simultaneously relates to a structure of an OLED display panel and a manufacturing method thereof, for avoiding unnecessary redundant description, the structure of the OLED display panel related to the present disclosure will be described as follow with reference to the manufacturing method thereof.

An embodiment of the present disclosure provides a manufacturing method of an OLED display panel, which can be separated into two stages. The first stage is a manufacturing stage of a thin film transistor (TFT) device functional layer, and the second stage is a manufacturing stage of a light emitting functional layer. For the first stage, methods related to the present disclosure are classified to be a step S1, and for the second stage, it is separated into a step S2 to step S7, and specifically as follows:

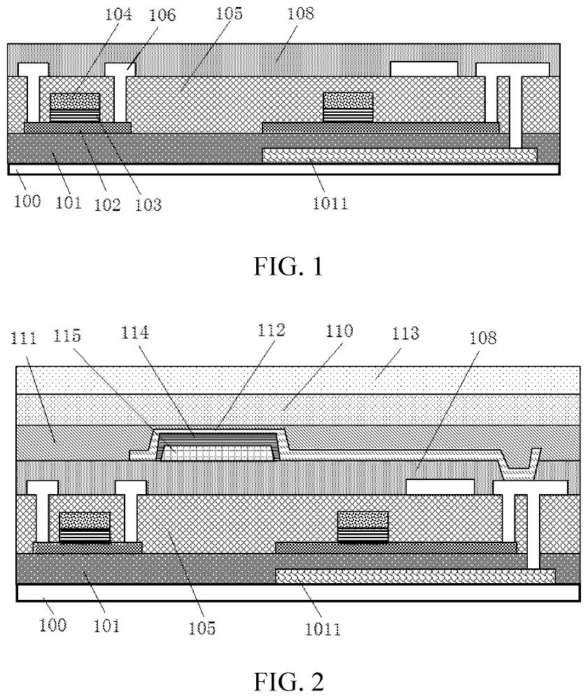

Step S1, providing a substrate 100, and forming the TFT device functional layer on the substrate. The finished structural diagram please refer to FIG. 1.

The functional layer includes the TFT device functional layer. Specifically, a light shielding (LS) layer 1011 and a buffer layer 101 are deposited on a glass substrate or on other base substrate 100, and they are performed patterning. Furthermore, the buffer layer 101 can be a single layer structure or a laminated structure, and specific used material can be SiOx, SiNx/SiOx, AlOx/SiOx, etc. After that, depositing indium gallium zinc oxide (IGZO) ora similar oxide semiconductor film layer 102, such as indium doped zinc oxide (IZO), indium gallium oxide (IGO), indium gallium tin oxide (IGTO), indium gallium zinc tin oxide (IGZTO), etc. on the buffer layer 101, and performing a patterning process on it.

After that, depositing a gate insulating (GI) layer 103 and a gate electrode (GE) layer 104, and performing a patterning process on them. Furthermore, the gate insulating layer 103 may be a single layer structure or a laminated structure, and specific used material can be SiOx, SiNx, AlOx, SiNx/SiOx, etc. The gate electrode layer 104 is preferred to be a Cu/Mo laminate, a Cu/MoTi laminate, a Cu/Ti laminate, an Al/Mo laminate, or a single layer with a CuNb alloy, etc.

After that, depositing an interlayer dielectric layer (ILD layer) 105, and performing a patterning process and a process of opening a hole on it. Furthermore, the ILD layer 105 may be a SiOx laminate, a SiOx/SiNx laminate, etc. Depositing a source/drain metal electrode (S/D) layer 106, and performing a patterning process on it. Furthermore, the S/D layer 106 is preferred to be a Cu/Mo laminate, a Cu/MoTi laminate, a Cu/Ti laminate, an Al/Mo laminate, ora single layer with a CuNb alloy, etc.

At last, depositing passivation (PV) layer 108. Furthermore, the passivation layer 108 may be a single layer structure or a laminated structure, and specific used material can be SiNx, SiOx, SiOx/SiOx, etc.

Furthermore, the functional layer includes the TFT device functional layer and the passivation layer thereon, and it is only an exemplary description. In other embodiment, the functional layer may be constituted by other device layers, the specific may be configured according to requirements and is not limited herein.

Furthermore, for the second stage of manufacturing the light emitting functional layer, the included steps are specific as follows, and the finished structural diagram please refer to FIG. 2.

Step S2, performing film formation and patterning of the color resist layer 115 on the passivation layer 108 of the TFT device functional layer.

Step S3, performing film formation and patterning of the planarization layer 114 on the color resist layer 115.

Step S4, performing film formation and patterning of the anode layer 113 on the planarization layer 114.

Step S5, performing film formation and patterning of the pixel definition layer 111 on the anode layer 113.

Step S6, manufacturing the OLED light emitting layer 110 on the pixel definition layer 111.

Step S7, manufacturing a cathode layer 112 and an encapsulation layer on the OLED light emitting layer (not shown in the figures).

For the pixel definition layer 111, the color resist layer 115, the planarization layer 114, the anode layer 113, the OLED light emitting layer 110, and the cathode layer 112 included by the light emitting functional layer, the present disclosure uses a new style structural configuration on some of the functional layers among them, thereby the OLED display panel related to the present disclosure overcoming the defect of the prior art, and specifically as follows:

Comparing the planarization layer 114 included by the OLED panel related to the present disclosure to the configuration way of covering with a large area by the planarization layer in the prior art, the present disclosure reduces the coverage area of the planarization layer 114, and only remains the planarization layer 114 on the light emitting region of the OLED light emitting layer, and makes the anode layer disposed on the planarization layer 114 to be flat, thereby preventing from a short circuit problem occurring between the anode layer and the cathode layer. The specific used method is that the coverage range of the planarization layer 114 and the coverage range of the color resist layer 115 disposed therebelow in the light emitting area are consistent, that is, the area of the planarization layer 114 is equal to the area of the color resist layer 115, thereby ensuring light emitted from the OLED light emitting layer 110 is performed a color filter process by the color resist layer 115.

Furthermore, for the included pixel definition layer 111, comparing it to a configuration way in the prior art that the pixel definition layer is higher than the anode and restricts the light emitting layer 110 therein, the present disclosure controls a height of the pixel definition layer 111 to be as same as a height of the anode layer 113 being planarization, that is, the heights of a top surface of the pixel definition layer 111 and the surface of the anode layer 113 being planarization are kept being equal, thereby effectively prevent from the pixel definition layer 111 affecting the light path of the outgoing light emitted from the OLED, and it can also improve the problem of the pixel definition layer 111 having remained photoresist.

Furthermore, the light emitting region defined by the OLED display panel related to the present disclosure is a sandwich structural region constituted by the anode layer 113, the OLED light emitting layer 110, and the cathode 112. Furthermore, comparing the present disclosure to a configuration way in the prior art that the light emitting is disposed in the pixel definition layer, the light emitting layer related to the present disclosure is realized by using a method of evaporating an entire surface of the OLED light emitting layer 110 on the pixel definition layer 111.

Furthermore, another aspect of the present disclosure is to provide a display device, including the OLED display panel related to the present disclosure.

The technical scope of the present disclosure is not limited to the above description, and those skilled in the art can make various modifications and changes to the above embodiments without departing from the technical idea of the present disclosure, and this modifications and changes are all within the scope of the present disclosure.

What is claimed is:

1. An organic light emitting diode (OLED) display panel, comprising:
a substrate, wherein a thin film transistor (TFT) device functional layer is disposed on the substrate;
a color resist layer disposed on a side of the TFT functional layer away from the substrate;
a planarization layer disposed on the color resist layer;
an anode layer disposed on a side of the planarization layer away from the color resist layer and electrically connected to the TFT device functional layer by a first via hole; and
an OLED light emitting layer disposed on the anode layer;
wherein a projection area of the planarization layer on the substrate is equal to a projection area of the color resist layer on the substrate.

2. The OLED display panel as claimed in claim 1, wherein a disposing method of the planarization layer makes a coverage range of the planarization layer be consistent with a coverage range of the color resist layer in a light emitting area of the OLED light emitting layer.

3. The OLED display panel as claimed in claim 1, wherein a pixel definition layer is disposed on the TFT device functional layer, and an opening area is disposed on the pixel definition layer, and the color resist layer, the planarization layer, and the OLED light emitting layer are disposed in the opening area on the planarization layer.

4. The OLED display panel as claimed in claim 3, wherein a surface of the pixel definition layer is flush with a surface of the anode layer disposed on the planarization layer.

5. The OLED display panel as claimed in claim 1, wherein a cathode layer and an encapsulation layer are disposed on the pixel definition layer.

6. A manufacturing method of the OLED display panel according to claim 1, comprising:
step S1, providing the substrate, and forming the TFT device functional layer on the substrate;
step S2, performing film formation and patterning of the color resist layer on the TFT device functional layer;
step S3, performing film formation and patterning of the planarization layer on the color resist layer;
step S4, performing film formation and patterning of the anode layer on the planarization layer;
step S5, performing film formation and patterning of the pixel definition layer on the anode layer; and
step S6, manufacturing the OLED light emitting layer on the pixel definition layer;
wherein in the step S3 and the step S4, after the patterning, projection areas of remained parts of the color resist layer and the planarization layer on the substrate are equal.

7. The manufacturing method as claimed in claim 6, wherein in the step S3 and the step S4, after the color resist layer and the planarization layer are performed the film formation and then are patterned, coverage ranges of the remained color resist layer and the remained planarization layer in a light emitting area of the OLED light emitting layer are consistent.

8. The manufacturing method as claimed in claim 6, wherein in the step S5, a height of a surface of the patterned pixel definition layer is consistent with a height of the anode layer on the planarization layer.

9. The manufacturing method as claimed in claim 6, wherein in the step S6, the OLED light emitting layer is evaporated with its entire surface on the pixel definition layer.

10. A display device, comprising the OLED display panel as claimed in claim 1.
